(19) United States
(12) Patent Application Publication
(10) Pub. No.: US 2015/0369899 A1
(43) Pub. Date: Dec. 24, 2015

(54) METHOD FOR CHARACTERISING AN ELECTRICAL CONNECTION DEVICE INTENDED TO BE HYBRIDIZED TO AN ELECTRONIC DEVICE

(71) Applicant: Commissariat a L'Energie Atomique et aux Energies Alternatives, Paris (FR)

(72) Inventor: Haykel BEN JAMAA, Grenoble (FR)

(73) Assignee: Commissariat a L'Energie Atomique et aux Energies Alternatives, Paris (FR)

(21) Appl. No.: 14/745,783

(22) Filed: Jun. 22, 2015

(30) Foreign Application Priority Data
Jun. 24, 2014 (FR) 14 55857

(51) Int. Cl. G01R 35/00; G01R 1/073

(52) U.S. Cl. CPC G01R 35/005; G01R 1/07314

(57) ABSTRACT

Method for characterizing an electrical connection device intended to be hybridized to an electronic device and comprising electrical connection elements each intended to be in electrical contact with at least one of a plurality of contact pads of the electronic device which are electrically connected together, including at least one step of selection of a reference electrical connection element from among said electrical connection elements, then, for the or each of the electrical connection elements other than the reference electrical connection element, the implementation of the following steps:
application of a reference electric voltage between the reference electrical connection element and said electrical connection element;
measurement of an electric current flowing through the reference electrical connection element and said electrical connection element, or of an electrical resistance between the reference electrical connection element and said electrical connection element, by varying the position of said electrical connection element with respect to one of the contact pads arranged opposite said electrical connection element;
determination of the existence of at least one value of a parameter linked to the position of said electrical connection element for which an electrical contact is correctly established between said electrical connection element and said contact pad.

### TECHNICAL FIELD AND PRIOR ART

The invention relates to a method for characterizing an electrical connection device intended to be hybridized to an electronic device, or circuit. The invention applies in particular to the characterization, or calibration, of a probe card intended to be used to test an electronic device comprising contact pads electrically connected together.

So-called “3D” electronic circuits and photonic circuits generally comprise contact pads made with a small pitch, or period, generally less than or equal to around 100 μm. These contact pads are of small size and mechanically fragile. They correspond for example to copper pillars made on thin layer silicon (thickness less than around 100 μm) and in metal interconnection levels and dielectric layers of low permittivity which are also mechanically fragile. These contact pads generally form vias, or TSV, made in the circuits.

The testing of the contact pads of such a circuit is generally carried out via the use of a probe card intended to be applied to the circuit with a certain pressure in order to obtain a good electrical contact between the probes and the contact pads.

FIG. 1 schematically represents such a probe card 10 comprising a first substrate 12, for example made of silicon (which is a material having a low coefficient of thermal expansion, or CTE). Probes 14 comprising an electrically conducting material, for example metal, are arranged on a front face of the first substrate 12. The first substrate 12 is integral, at a rear face, with a second substrate 16 generally made of an organic or ceramic material of higher CTE than that of the material of the first substrate 12 and which makes it possible in particular to assure electrical connections between the probes 14 and an electronic test device. Connection beads 18 assure the electrical connections and the mechanical holding between the second face of the first substrate 12 and the second substrate 16.

The probes 14 are placed in contact with contact pads 20 of an electronic device 22 made in a substrate 24 during a testing of the device 22. Ideally, the probes 14 and the contact pads 20 are arranged along two parallel planes and when the probe card 10 is applied to the device 22, all of the probes 14 penetrate slightly into the contact pads 20, thus creating electrical contacts between each of the probes 14 and one of the contact pads 20. In reality, as shown in FIG. 1, the probe card 10 most often has a non-flat, generally curved shape due in particular to the heat treatments implemented during the production of the probe card 10 which create mechanical stresses and deformations due to the different CTE of the materials used. In practice, the ends of the probes 14 are thus not all arranged at a same level, in a single plane. When the probes 14 are applied against the contact pads 20, some of said probes 14, particularly those situated near the edges of the probe card 10, may not be in contact with the contact pads 20 arranged opposite said probes 14. Furthermore, other probes 14, particularly those located at the center of the probe card 10, may be driven in too deeply into the contact pads 20 arranged opposite said probes 14, causing damaging or even destruction of said contact pads and thereby preventing the formation of a correct electrical contact.

The force with which the probes 14 are applied onto the contact pads 20 of the device 22 must be high enough to obtain a sufficiently low contact resistance between the probes 14 and the contact pads 20. But this force must also not be too high so that the probes 14 are not driven too much into the contact pads 20 so as not to damage them. There is thus a compromise to be found between the contact resistance which is improved by applying a moderate to high force, and the mechanical strength of the contact pads which are fragile which is protected by applying a moderate or low force.

The difficulty consists in observing and defining this compromise before the test operation. A probe card must be able to meet this compromise. The probe card of small pitch contains a high number of test probes, generally several thousand. In certain cases, the compromise is found for a set of test probes but not for the totality of the probes.

Ideally, a probe card is produced using a reference device which is a circuit manufactured as faithfully as possible to the functional electronic, or real device intended to be tested, and which is used to characterize the probe card. The reference device reproduces all of the technological and geometric characteristics of the functional electronic device while making it possible to establish electrical connections between the contact pads to carry out electrical measurements from the probe card which make it possible to estimate the force to apply to the probes in such a way that the compromise relative to the force with which the probe card is applied against the electronic device is found for all of the probes.

Resorting to a reference device produced using the same technological method as the functional electronic device may nevertheless be very expensive. In fact, a low number of reference devices is generally required but its manufacture may involve very expensive technology (the same as that enabling the manufacture of the functional electronic device) which is only justified when the production volume is high.

As an alternative, it is possible to use a functional electronic device to test and characterize the probe card if it is inappropriate to manufacture a reference device for cost reasons. Nevertheless, the electrical connections present in the functional electronic device may not be suitable for characterizing correctly the probe card.

The document U.S. Pat. No. 8,421,491B2 describes a probe card in which the differences in overall topologies of the card may be compensated by modulating the thickness of a piezoelectric layer of the probe card via the application of an electric voltage to said piezoelectric layer, thereby modifying the position of the set of probes. This method nevertheless does not take into account the local topology of the card, that is to say at different regions of the probe card considered individually. Moreover, such a probe card does not make it possible to take account of the fragility of the electronic device tested, for example when the electronic device tested comprises thinned silicon as in the case of 3D integration or photonic circuits.

This problem described above for probe cards is also found in the more general field of permanent hybridization (for example for the production of so-called “3D” electronic circuits, that is to say electronic circuits comprising devices stacked one upon another, the probes corresponding in this case to “micro-inserts”) or temporary hybridization (corresponding for example to the case described previously in which a probe card is hybridized to an electronic device during a test) between electronic devices or circuits, in which electrical connection elements of a connection device are intended to be placed in contact with the contact pads of an electronic device.

### DESCRIPTION OF THE INVENTION

Thus there is a need to propose a method for characterizing an electrical connection device intended to be hybridized to an electronic device via a placing in contact of electrical connection elements of the electrical connection device with contact pads of the electronic device, making it possible to determine whether there exists at least one good positioning of the electrical connection device vis-á-vis the electronic device making it possible to have a good electrical contact between all of the electrical connection elements and the contact pads.

Another aim is also to propose such a characterization method which can be implemented from an electronic device corresponding to a reference device comprising contact pads adapted to such a characterization method or instead to a functional electronic device of which at least one part of the contact pads are electrically connected together.

Another aim is also to propose such a characterization method which takes account of the local topology of the electrical connection device and the fragility of the contact pads of the electronic device.

For this, one embodiment proposes a method for characterizing an electrical connection device intended to be hybridized to an electronic device and comprising electrical connection elements each intended to be in electrical contact with at least one of a plurality of contact pads of the electronic device which are electrically connected together, including at least one step of selection of a reference electrical connection element from among said electrical connection elements then, for the or each of the electrical connection elements other than the reference electrical connection element, the implementation of the following steps:
application of a reference electric voltage between the reference electrical connection element and said electrical connection element;
measurement of an electric current flowing through the reference electrical connection element and said electrical connection element, or of an electrical resistance between the reference electrical connection element and said electrical connection element, by varying the position of said electrical connection element with respect to one of the contact pads arranged opposite said electrical connection element;
determination of the existence of at least one value of a parameter linked to the position of said electrical connection element for which an electrical contact is correctly established between said electrical connection element and said contact pad.

Thus, this method makes it possible to determine whether there exists at least one good position of an electrical connection element with respect to a contact pad situated opposite the electrical connection element which makes it possible to obtain a good electrical contact between said electrical connection element and said contact pad, and does so for a set of electrical connection elements which are intended to be coupled with contact pads which are electrically connected together. It is then possible, by combining the results obtained for the different electrical connection elements, to determine whether there exists at least one position of the electrical connection device making it possible to have a correct electrical contact for said electrical connection elements or for all of the electrical connection elements of the electrical connection device, and thus to determine whether the electrical connection device is suitable for a hybridization with the electronic device.

This characterization method may be implemented from an electronic device corresponding to a reference device, which makes it possible in this case to characterize all of the electrical connection elements of the electrical connection device, or instead to a functional electronic device in which at least one part of the contact pads are electrically connected together, which makes it possible in this case to characterize the electrical connection elements which are intended to be coupled with said contact pads electrically connected together.

Finally, due to the fact that the electrical contact obtained is characterized individually at the different electrical connection elements, this characterization method takes good account of the local topology of the electrical connection device and the fragility of the contact pads of the electronic device.

Such a method applies advantageously to the characterization of an electrical connection device and an electronic device of which the electrical connection elements and the contact pads are made with a small pitch (for example less than or equal to 100 μm) but may also apply for larger pitches.

An electrical contact between an electrical connection element and a contact pad may be considered as being correctly established when the electrical resistance of said contact is between around 1Ω and 100 kΩ, or between around 1Ω and 10 kΩ. When the electrical resistance is less than around 1Ω, the contact resistance is termed very low or abnormally low, and the contact practically represents a short circuit. An electrical contact between an electrical connection element and a contact pad may be considered as practically inexistent when the electrical resistance of said contact is between around 100 kΩ and 100 MΩ. When said resistance is greater than around 100 MΩ, the resistance is termed very high or abnormally high, and the contact practically represents an open circuit.

The electrical connection device may comprise a probe card and the electrical connection elements may comprise electrical connection probes. The electrical connection elements may correspond to probes or multi-probe elements. Each probe may comprise a pointed, domed or flat end. A shape is termed domed when it represents a portion of a sphere, such as a hemisphere, or that it is of rounded shape. Unlike a domed shape, a shape is termed flat when it is defined in a plane.

The step of measurement of the current or of the electrical resistance may be carried out from a first position of said electrical connection element in which said electrical connection element is not in contact with said contact pad and at least up to a second position of said electrical connection element from which the current or the electrical resistance measured no longer varies uniformly. A uniform variation may be defined as being a variation in which the spectral transformation (for example the Fourier transform) does not undergo a large dispersion around zero. For example, an almost constant or more or less linear or more or less polynomial variation may be considered as uniform.

The second position of said electrical connection element may correspond to a position from which the variations in the value of the current or in the electrical resistance measured form noise or correspond to non-coherent oscillations which indicate the start of a deterioration of the contact pad with which the electrical connection element is placed in contact (formation of an open circuit or a short circuit at said contact pad). Between the first and second positions, the current or the electrical resistance can vary, in a part of this interval of positions, uniformly while forming a plateau.

The step of measurement of the current or the electrical resistance may be carried out up to a third position of said electrical connection element forming an open circuit or a short circuit at said contact pad. Generally speaking, the step of measurement of the current or the electrical resistance may be implemented up to a third position in which a very high (for example greater than around 100 MΩ) or very low (for example less than around 1Ω) electrical resistance between said electrical connection element and said contact pad is obtained.

The variation of the position of said electrical connection element with respect to said contact pad may be carried out by varying a pressure with which the electrical connection device is applied against the electronic device, said pressure corresponding to the parameter linked to the position of said electrical connection element.

In a variant, each electrical connection element of the electrical connection device may comprise a controllable element, or means, able to modify the position thereof with respect to a contact pad of the electronic device arranged opposite the electrical connection element independently of the position of the other electrical connection elements and as a function of the value of a configuration electric voltage applied to the controllable element, or means, and the variation of the position of said electrical connection element with respect to said contact pad may be carried out by varying the configuration electric voltage applied to the controllable element, or means, of said electrical connection element, said configuration electric voltage being able to correspond to the parameter linked to the position of said electrical connection element.

In this case, each electrical connection element may comprise at least:
one support of which at least one first end is anchored to a substrate of the electrical connection device such that a part of the support is suspended above a front face of the electrical connection device, the support comprising at least one portion of piezoelectric material arranged between two electrodes and able to move said part of the support in a two-directional manner substantially perpendicularly to the front face as a function of the value of the configuration electric voltage applied to the electrodes;
one electrically conducting element arranged on said part of the support.

In the case of an electrical connection device corresponding to a probe card, the electrically conductive elements may correspond to the electrical connection probes of the card.

The determination of the existence of at least one value of a parameter linked to the position of said electrical connection element and for which an electrical contact is correctly established between said electrical connection element and said contact pad may comprise at least the implementation of the following steps:
determination of a value Fmin of the parameter linked to the position of said electrical connection element for which the electrical contact between said electrical connection element and said contact pad is correctly established and from which the current or the electrical resistance measured varies uniformly;
determination of a value Fmax of the parameter linked to the position of said electrical connection element for which the electrical contact between said electrical connection element and said contact pad is correctly established and from which the current or the electrical resistance measured no longer varies uniformly;
determination of an interval of values [X % of Fmin; Y % of Fmax], X and Y being coefficients of values between around 75 and 125.

In this case, the method may further comprise a step of determination of the existence of an intersection of the intervals of values [X % of Fmin; Y % of Fmax] for all or part of the electrical connection elements other than the reference electrical connection element.

Thus, it is possible to determine a range of values of the parameter linked to the position of said electrical connection element, for example the pressure with which the electrical connection device is applied against the electrical device or the configuration voltage applied to the means for controlling the position of the electrical connection elements, for which an electrical contact is correctly established for the set of electrical connection elements tested, and thus without degradation or destruction of the contact pads arranged opposite said electrical connection elements. For such a range of values, the electrical connection device is thus perfectly functional for hybridization with the electronic device.

The value of Fmax may correspond to the value of the parameter linked to the position of said electrical connection element (for example Pmax when this parameter corresponds to the pressure with which the electrical connection device is applied against the electrical device, or Vmax when this parameter corresponds to the configuration voltage applied to the means of controlling the position of the electrical connection elements) for which the electrical connection element situated in the second position (that from which the current or the electrical resistance measured no longer varies uniformly).

The determination of at least one value of a parameter linked to the position of said electrical connection element and for which an electrical contact is correctly established between said electrical connection element and said contact pad may further comprise a step of determination of a value Fdest of the parameter linked to the position of said electrical connection element from which a variation of the current or the electrical resistance measured increases due to a deterioration of said contact pad, and the method may further comprise, when it is determined that an intersection of the intervals of values [X % of Fmin; Y % of Fmax] does not exist, a step of determination of the existence of an intersection of the intervals of values [X % of Fmin; Z % of Fdest] determined previously, with Z between around 75 and 95.

The existence of an intersection of the intervals of values [X % of Fmin; Z % of Fdest] may thus make it possible to identify a range of values of the parameter linked to the position of said electrical connection element for which the electrical connection device is partially functional for hybridization with the electronic device.

Said plurality of contact pads of the electronic device may correspond to the set of contact pads of the electronic device. Such a configuration corresponds for example to an electronic device corresponding to a reference device, or instead to a functional electronic device enabling access to all of its contact pads such as for example a routing electronic device such as an interposer.

In a variant, said plurality of contact pads of the electronic device may correspond to a part of the set of contact pads of the electronic device, and when the set of contact pads of the electronic device comprises other contact pads of the electronic device which are electrically connected together and distinct from said plurality of contact pads, the steps of the method may be repeated for other electrical connection elements of the electrical connection device which are intended to be in contact with said other contact pads. The different groups of contact pads electrically connected together may correspond to electrical supply contact pads of the electronic device and/or ground contact pads of the electronic device.

In this case, the method may further comprise, when it is determined that an intersection of the intervals of values [X % of Fmin; Y % of Fmax] exists, a step of calculation by interpolation of an interval of values [X % of Fmin; Y % of Fmax] for each of the electrical connection elements of the electrical connection device for which an interval of values [X % of Fmin; Y % of Fmax] has not been determined previously and, when it is determined that an intersection of the intervals of values [X % of Fmin; Z % of Fdest] exists, a step of calculation by interpolation of the intervals of values [X % of Fmin; Z % of Fdest] for each of the electrical connection elements of the electrical connection device for which an interval of values [X % of Fmin; Z % of Fdest] has not been determined previously.

In the above paragraphs, the values Fmin, Fmax and Fdest may be called Pmin, Pmax and Pdest when the parameter considered is the pressure with which the electrical connection device is applied against the electronic device, or be called Vmin, Vmax and Vdest when the parameter considered is the configuration electric voltage applied to the means controlling the position of the electrical connection elements with respect to the contact pads.

When the parameter considered is the configuration electric voltage, the determination of at least one value of a parameter linked to the position of said electrical connection element and for which an electrical contact is correctly established between said electrical connection element and said contact pad may comprise at least the implementation of the following steps:
determination of a value Vmin of the configuration electric voltage for which said electrical connection element is not in contact with said contact pad;
determination of a value Vmax of the configuration electric voltage for which an electrical contact is correctly established between said electrical connection element and said contact pad without deteriorating said contact pad.

The values Vmin and Vmax may be memorized in order that each electrical connection element can be positioned in the desired position (absence or not of contact with the pad situated opposite) during the hybridization.

The value Vmax of the configuration electric voltage can position said electrical connection element in an intermediate position between a first position for which an electrical contact is correctly established between said electrical connection element and said contact pad and from which the current or the electrical resistance measured varies uniformly and a second position for which an electrical contact is correctly established between said electrical connection element and said contact pad and from which the current or the electrical resistance measured no longer varies uniformly.

### BRIEF DESCRIPTION OF THE DRAWINGS

The present invention will be better understood on reading the description of embodiment examples given purely for illustrative purposes and in no way limiting, while referring to the appended drawings among which: determined previously, with Z between around 75 and 95.

FIG. 1 schematically represents a probe card hybridized to an electronic device;

FIG. 2 represents a block diagram of a method for characterizing an electrical connection device according to a first embodiment;

FIGS. 3 and 4 represent examples of measurements of an electric current carried out during a method for characterizing an electrical connection device;

FIG. 5 represents a block diagram of a method for characterizing an electrical connection device according to a second embodiment;

FIG. 6 represents an example of embodiment of an electrical connection element with configurable position;

FIGS. 7 and 8 represent examples of measurements of an electrical current carried out during a method for characterizing an electrical connection device;

FIG. 9 represents a block diagram of a method for characterizing an electrical connection device according to a third embodiment.

Identical, similar or equivalent parts of the different figures described hereafter bear the same numerical references so as to make it easier to go from one figure to the next.

The different parts shown in the figures are not necessarily given at a uniform scale, in order to make the figures more legible.

The different possibilities (variants and embodiments) should be understood as not being mutually exclusive and may be combined together.

### DETAILED DESCRIPTION OF PARTICULAR EMBODIMENTS

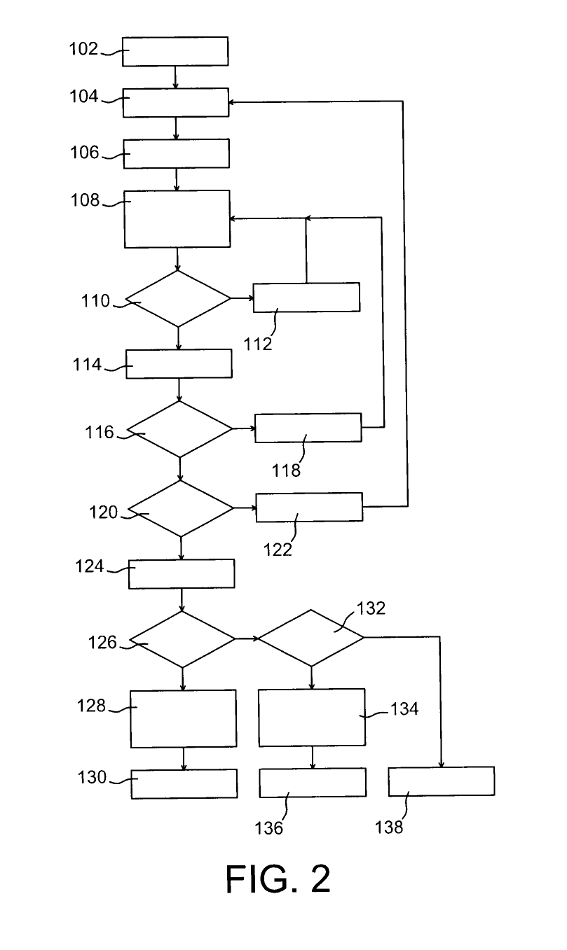

FIG. 2 represents as a block diagram a method for characterizing an electrical connection device, here a probe card, according to a first embodiment, making it possible to determine whether the probe card may be used or not for carrying out the testing of a given electronic device. This first embodiment is for example implemented when a part only of the probes, that is to say the electrical connection elements, of the probe card are intended to be tested, for example when no reference device is available and when the functional electronic device used for this method comprises contact pads of which a part only are, or may be, electrically connected to each other to be used for testing the probes situated opposite said pads, such as pads forming part of one or more electrical supply networks of the electronic device and/or pads forming part of one or more ground networks of the electronic device.

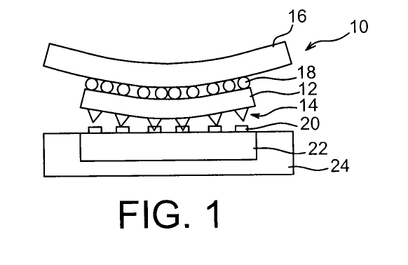

This method is implemented from a probe card similar to the probe card 10 described previously in conjunction with FIG. 1.

In a variant, each probe 14 may correspond to a single probe or to a multi-probe, that is to say a set of several probes, for example three probes. Such multi-probe elements are well suited to form electrical contacts with domed shape and hard contact pads, corresponding for example to metal beads, because in this case, such contact pads can easily be inserted between the probes of each of the multi-probe elements. The multi-probe elements are thus well centered with respect to the contact pads of the device tested and avoid degrading such rounded and hard contact pads. A distance between the tips of two probes of such a multi-probe element is for example less than around 15 μm.

According to another variant, the probes 14 may correspond to portions of electrically conductive material in which the tip is of domed or flat shape. Such a conducting portion comprises for example a flux metal such as SnAg or NiAu, the hardness of which is less than the metal forming the probes 14 in which the tip is pointed, or instead a harder metal such as tungsten. Such elements are well suited to form an electrical contact with the contact pads of the device tested which are not well suited to a contact by probes of which the ends are pointed, such as for example copper pads surrounded with insulator forming a flat surface for example intended to be transferred onto a chip by direct bonding. Such elements make it possible to conserve the integrity of the contact pads. The form factor, or aspect ratio, of these conducting portions may be greater than 1 or even greater than 10 or 30. Such a high aspect ratio is advantageous when a great mechanical flexibility is required, or when the spacing between the conducting portion and the contact pad is variable or high. The aspect ratio, called AR, of such a conducting portion or of a probe is defined by the following formula:

AR=H/(4πS)^{1/2}

with H corresponding to the height of the probe or the conducting portion (dimension along the Z axis), and S corresponding to the surface of its projection in the plane of the substrate (parallel to the plane (X,Y)).

A step 102 firstly consists in selecting, from among the set of probes 14 of the probe card 10, a set T of probes intended to be tested, for example those that are situated opposite contact pads corresponding to at least one part of the pads of the electronic device and which are electrically connected to each other. Said set T may correspond to a set of probes situated opposite pads forming part of an electrical supply network of the electronic device or of a ground network of the electronic device.

During a step 104, a reference probe A, or reference electrical connection element, is selected from among the probes of the set T. The reference probe A is selected from among the probes of the set T preferably such that it corresponds to that having the minimum electrical resistance with the electrical lines that connect it to the other probes.

During a step 106, a test probe B is selected from among the probes of the set T other than the reference probe A.

A reference electric voltage Vref is applied to the terminals of the test B and reference A probes, and a pressure P is then applied to the probe card 10 in order to create probes in contact with the electronic device (step 108). A current I flowing between the reference probe A and the test probe B (and which thus also passes through the two contact pads with which the probes A and B are in contact) is then measured (step 108). This measurement of the current is carried out by progressively increasing the value of the pressure P, for example until ending up with an open circuit or a short circuit at the contact pad situated against the test probe B.

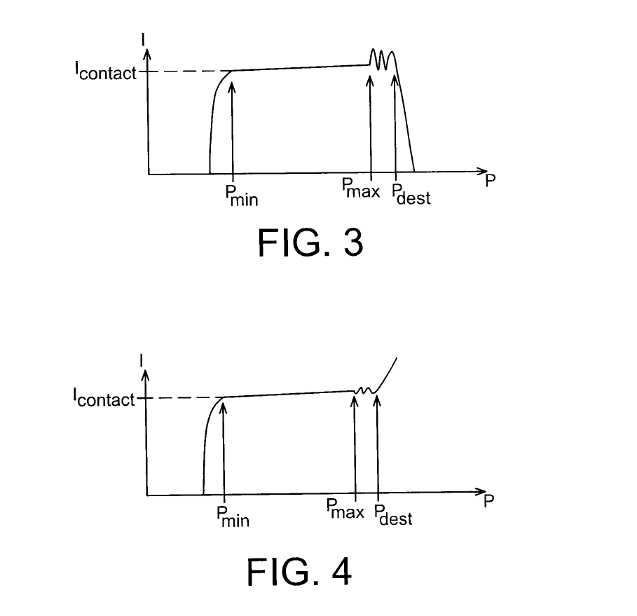

FIG. 3 represents a first example of current I thus measured as a function of the value of P. In this figure, the current I passes rapidly from a zero value (due to the absence of contact of at least one of the probes A or B with the corresponding contact pad) to a first value called Icontact at a first value of P called Pmin. This first value Icontact corresponds to the value of the current which flows once an electrical contact between the test probe B and the contact pad is found opposite the test probe B and once an electrical contact between the reference probe A and the contact pad situated opposite the reference probe A are correctly established (being able to correspond to a break of a native oxide present on said contact pads by the probes A and B). The value of P is incremented until it reaches a second value of P called Pmax. This value of Pmax corresponds to the value of P above which the value of I no longer increases in a substantially constant or uniform manner (between Pmin and Pmax, the value of I increases in a uniform or constant manner, which results in the formation of a plateau on the curve I(P) measured between Pmin and Pmax, due to the progressive penetration of the probes into the contact pads which improves the electrical contacts and thus reduces the electrical resistance between the probes and the contact pads). Above Pmax, the value of I no longer varies uniformly and the variations in the current correspond to noise (or instead non-coherent oscillations). The presence of this noise may be for example identified via a Fourier transform carried out on the values I(P). The value of P is further incremented until it reaches a third value of P called Pdest. This value of Pdest corresponds to the value of P above which the value of I drops abruptly until becoming zero, which reflects the start of the formation of an open circuit at at least one of the contact pads associated with the reference A and test B probes (break of a part of the BEOL (Back-End Of Line) of the device at said contact pads). The detection of the break of the BEOL makes it possible to anticipate this phenomenon during an elastic phase of the deformations (just before an irreversible deformation), such that the measurement is stopped before the irreversible break takes place.

In the method described in conjunction with FIG. 2, a decision is taken during a step 110 in order to know whether the pressure Pdest is reached or not (via the detection of the abrupt drop in the value of I). If the pressure Pdest is not reached, the value of P is incremented (step 112). If the pressure Pdest is reached, the method passes to a step 114 during which the values of Pmin, Pmax and Pdest are determined (for example via calculations from the curve I(P) carried out using a computer).

In the example described above, from the pressure Pdest, the value of I drops abruptly due to the appearance of an open circuit. In a variant, it is possible that a short circuit occurs at at least one of the contact pads associated with the reference A and test B probes, instead of the appearance of an open circuit. Such a short circuit is also the consequence of a break of the BEOL. The break of the BEOL may thus cause an open circuit or a short circuit depending on the configuration of the final defect.

FIG. 4 represents a second example of current I measured as a function of the value of P in which, above the value of Pdest, the value of I does not drop abruptly but on the contrary increases abruptly with respect to the value Icontact due to the appearance of the short circuit.

In all cases, the appearance of a noise on the curve I(P) from Pmax signifies that the value Pdest is soon reached.

In a variant of the measurement of the current flowing as a function of the pressure, given that the value Vref is constant, it is possible to measure the variation in the electrical resistance between the probes A and B as a function of the pressure P. In this case, between P=0 and P=Pmin, the value of the resistance passes abruptly from an infinite value to a value Rcontact. Between Pmin and Pmax, the value Rcontact drops slightly on account of the improvement of electrical contact due to the penetration of the probes into the contact pads. Between Pmax and Pdest, noise is observed, as for the case of the measurement of the current. Above Pdest, the value of the resistance increases or drops abruptly depending on whether an open circuit or a short circuit appear at at least one of the contact pads. The determination of the values Pmin, Pmax and Pdest at step 114 is carried out from the measurements R(P).

During a step 116, it is determined whether all of the probes of the set T (apart from the reference probe A) have been tested. If this is not the case, a probe of the set T which has not yet been tested is selected as being the new test probe B (step 118) and steps 108 to 116 are then repeated with this new test probe B.

When all the probes of the set T, apart from the reference probe A, have been tested, the method passes to step 120 during which it is determined whether there remain other probes to test, for example probes situated opposite contact pads of another electrical supply network or another ground network of the electronic device and which have not yet been tested. If this is the case, a new set T of probes to be tested is selected (step 122) and steps 104 to 120 are repeated from this new set T of probes.

When all of the probes to be tested have been tested, all the values Pmin, Pmax and Pdest determined are for example grouped together in a specific computer file. These values are superimposed then compared with each other (step 124).

During a step 126, it is determined whether there exists an intersection of the intervals of values [Pmin; Pmax] determined previously (step 126). If this is the case, it signifies that one or more values of the pressure P for which a good electrical contact is possible simultaneously between all of the probes tested and the contact pads which are situated opposite said probes exist, without destruction of said contact pads. In this case, knowing the geometric shape of the probe card 10 (for example a curved shaped in the example of the card shown in FIG. 1), the values of the intervals [Pmin; Pmax] for the probes not tested (for example those situated opposite contact pads which are not electrically connected together) are calculated by interpolation, then an intersection I of all the intervals [Pmin; Pmax] (both those of the probes tested and those of the probes not tested) is determined (step 128), which makes it possible to determine one or more values of the pressure P for which a good electrical contact is possible simultaneously between all of the probes of the card 10 and all of the contact pads of the electronic device, without destruction of said contact pads (step 130). The probe card 10 is then considered as perfectly functional for this or these pressure P values, and can be used to carry out tests on electronic devices similar to the electronic device used during this test method.

If no intersection exists for all of the intervals of values [Pmin; Pmax] determined previously for the probes tested, it is then determined whether there exists an intersection for the intervals of values [Pmin; Z % of Pdest], with Z which is for example equal to 90, or between around 75 and 95 (step 132). If this is the case, it signifies that one or more values of the pressure P for which an electrical contact is possible between the probes tested and the contact pads which are located opposite said probes exist, with nevertheless a risk of elastic or irreversible mechanical destruction or degradation of certain of said contact pads. In this case, knowing the geometric shape of the probe card 10, the values of the intervals [Pmin; Z % of Pdest] for the probes not tested are calculated by interpolation, then an intersection I of all the intervals [Pmin; Z % of Pdest] is determined (step 134), which makes it possible to determine one or more values of the pressure P for which an electrical contact is possible between all of the probes of the card and all of the contact pads (step 136). The probe card 10 is then considered as partially functional for this or these pressure P values, and may be used all the same to carry out tests on electronic devices similar to the electronic device used during said test method.

If no intersection exists for the intervals of values [Pmin; Z % of Pdest] determined previously for the probes tested, the probe card 10 is then considered as non-functional (step 138) and will not be used for the test of electronic devices similar to the electronic device used during said test method.

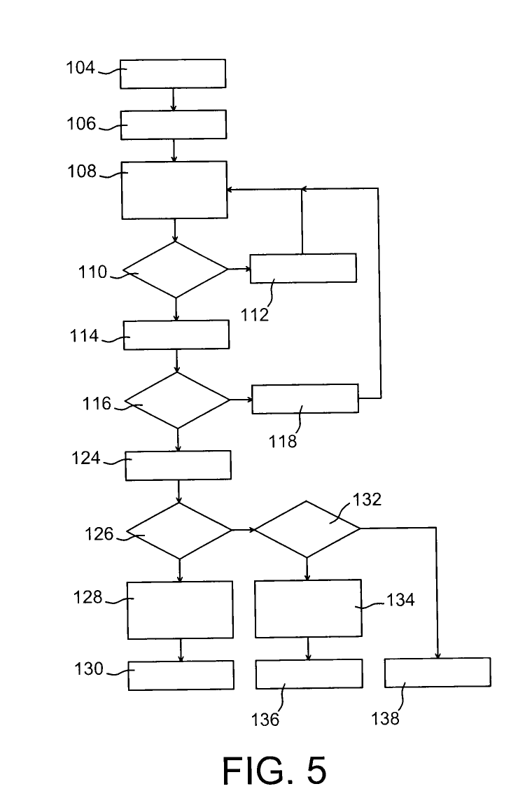

FIG. 5 represents as a block diagram a method for characterizing an electrical connection device, here a probe card, according to a second embodiment, making it possible to determine whether the probe card may be used or not to carry out the testing of a given electronic device. This second embodiment is implemented when all of the probes, that is to say all of the electrical connection elements, of the probe card are intended to be tested, for example when a reference device may be used for this test or when the contact pads of the functional electronic device used for this method may all be electrically connected to each other, for example when the functional electronic device is a routing device such as a passive interposer. In this case, the contact pads of the electronic device may be electrically connected together at a rear face of the electronic device, for example thanks to a temporary conducting layer short circuiting the pads, the probes being intended to come into contact with the pads at a front face of the electronic device.

In this second embodiment, the step 104 during which a reference probe A is selected from among the probes of the card is firstly implemented, without the prior implementation of a step of selection of a set T of probes since all of the probes will be tested.

A test probe B is then selected, said test probe B being different to the reference probe A (step 106).

Steps 108 to 118 described previously in conjunction with the first embodiment are then implemented. The values Pmin, Pmax and Pdest are then determined for all the probes of the probe card. These values are superimposed then compared with respect to each other (step 124).

Steps 126 to 138 described previously in conjunction with the first embodiment are then implemented in order to determine whether the probe card is perfectly functional, partially functional or non-functional, and thus to know whether said card may be used for the testing of said electronic device.

In the embodiments described previously, a pressure P applied to the probe card is considered as corresponding to the parameter linked to the position of the probes with respect to the contact pads. In a variant, it is possible to take into account a force applied to the probe card, or another parameter linked to the position of the probes with respect to the contact pads.

According to a variant of these two embodiments, steps 132, 134 and 136 may be omitted. In this case, the test method makes it possible only to determine whether the probe card is perfectly functional or non-functional.

According to another variant, for the implementation of steps 126 and 128, it is possible to take into account an interval other than [Pmin; Pmax]. For example, if an additional safety margin is desired to guarantee the absence of destruction of the contact pads, it is possible to take into account, instead of this interval, the values of 110% of Pmin and/or those of 90% of Pmax, or instead an even more restricted interval. It is possible to consider for example the intervals [X % of Pmin; Y % of Pmax], with X and Y between around 75 and 120. Furthermore, for the implementation of steps 132 and 134, it is possible to take into account an interval other than [Pmin; Z % of Pdest], for example [X % of Pmin; Z % of Pdest].

Such a characterization method may also be implemented for an electrical connection device of which the electrical connection elements comprise means making it possible to adjust individually the position of the electrical connection elements with respect to the electronic device.

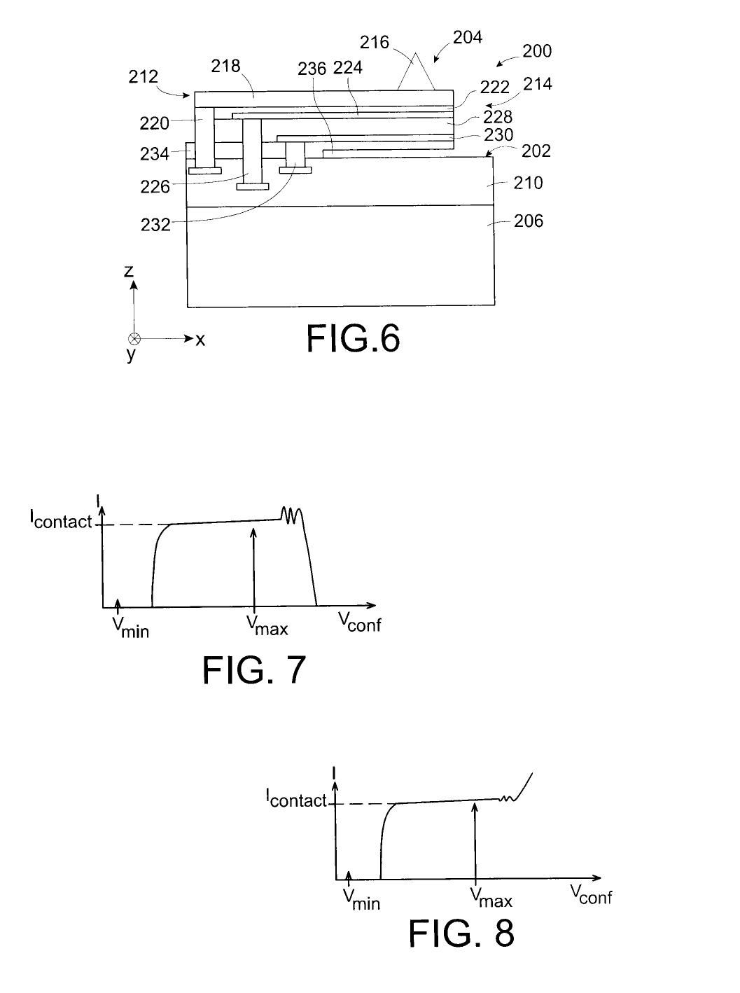

An example of embodiment of such an electrical connection device 200, which corresponds to a probe card, is shown in FIG. 6. The card 200 includes, on a front face 202, electrical connection elements 204 intended to be coupled to contact pads of the electronic device tested. In FIG. 6, although the card 200 comprises a number of elements 204 for example equal to several hundred, or several thousand or several tens of thousands, and arranged for example in a matrix, a single element 204 is shown.

The card 200 comprises a substrate 206 including for example semi-conductor such as silicon. One or more electrical interconnection layers (BEOL), not visible in FIG. 6, are arranged on the substrate 206, on the side of the front face 202, and form, in several dielectric layers 210 comprising at least one inorganic material such as SiO₂, SiON, SiN, etc., and deposited on a front face of the substrate 206, one or more electrical interconnection levels connected in particular to the elements 204.

Each element 204 is here produced as a flexible membrane comprising a first end 212 anchored to the substrate 206 and a free second end 214, that is to say not integral with the substrate 206, at which is arranged an electrically conducting element 216, corresponding to a test probe, or an insert, intended to be in contact or not with a contact pad of the device tested depending on the position of the element 204. The element 216 advantageously comprises metal such as copper, tungsten, aluminium, nickel or rhodium, or instead a semi-conductor covered with metal. The element 216 is intended to be applied against a contact pad of the device tested with a force enabling a mechanical penetration of the element 216 into the contact pad of the device tested. The material(s) of the element 216 are chosen in particular as a function of the desired hardness to form the contact with the contact pad of the device tested, and thus as a function in particular of the fragility of said contact pad.

The element 216 is arranged on an electrically conducting portion 218 here comprising an elongated shape and corresponding to an element of the flexible membrane. The portion 218 comprises at least one electrically conductive material such as doped or silicided silicon, and/or metal (for example copper, aluminium, tungsten or nickel, or one of those described above for the element 216) and/or graphite. The portion 218 is connected to one of the electrical interconnection levels through a first conducting pad 220.

A dielectric portion 222 is arranged between the portion 218 and a first electrode 224 comprising for example a metal such as titanium. The first electrode 224 is connected to one of the electrical interconnection levels through a second conducting pad 226. The first electrode 224 is arranged on a portion of piezoelectric material 228, comprising for example PZT and/or AIN, itself arranged on a second electrode 230. The second electrode 230 is connected to one of the electrical interconnection levels through a third conducting pad 232. The second electrode 230 and the portion 228 rest on an anchoring portion 234, for example made of semi-conductor such as silicon or made of a dielectric material (an electrical conduction with this portion being able in this case to be formed by an additional conducting via if necessary), of which a first part rests on the dielectric layers 210 and thus forms the anchoring of the first end 212 of the element 204 to the substrate 206. The conducting pads 220, 226 and 232 pass through this first part of the portion 234. A second part of the portion 234 does not rest on the dielectric layers 210 but is suspended above the front face 202 while forming a space 236 between the element 204 and the dielectric layers 210.

When a polarization voltage Vconf is applied to the terminals of the electrodes 224, 230 via the conducting pads 226 and 232, the portion of piezoelectric material 228 bends, under the effect of the electrostatic polarization, either in a direction of the front face 202, which reduces the thickness of the space 236 at the second end 214 (there may even be a contact between the second end 214 and the front face 202), or in an opposite direction thereby increasing the thickness of the space 236 at the second end 214. The position of the element 216 along the Z axis (axis oriented perpendicularly to the direction along which extends the membrane formed by the element 204, the Z axis also being perpendicular to the plane formed by the front face 202) is thus a function of the value of the polarization voltage Vconf applied to the terminals of the electrodes 224, 230. The element 216 may thus be positioned according to at least three different positions: a first lower position when the membrane bends in the direction of the substrate 206, a second intermediate position when no polarization voltage is applied to the terminals of the electrodes 224, 230 (case shown in FIG. 6), and a third upper position when the membrane bends in the direction opposite to that towards the substrate 206. Thus, when the element 216 is intended to be in contact with a contact pad of the device tested, said element 216 may be configured in the upper position. When the element 216 is intended not to be in contact with a contact pad situated opposite the element 216, it may be either left in the intermediate position, or configured in the lower position in order to avoid any risk of contact between the element 216 and the contact pad.

The electrical polarization voltages Vconf may be applied to the terminals of the electrodes 224, 230 of the elements 204 either by means of a device external to the card 200 and connected to the electrical interconnection levels of the card 200, or by means of memory points made in the card 200, for example in the dielectric layers 210, and which output for example signals corresponding to the polarization voltages Vconf to the terminals of the electrodes 224, 230.

The elements 216 may be connected to a test system, or interface (not shown in FIG. 6) via the portions 218, the pads 220 and the electrical interconnection layers, to inject or plot a signal (voltage or current) from or to the elements 216.

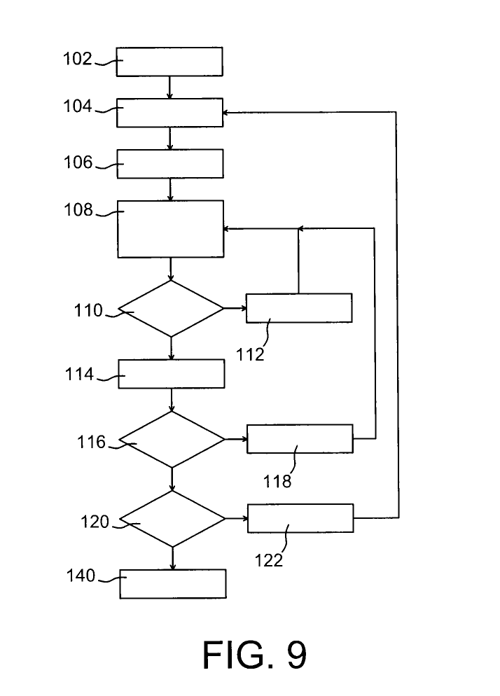

With such electrical connection elements, the position of which is controllable individually, the characterization method implemented may make it possible to determine, for each of the electrical connection elements, the values Vmin and Vmax of the polarization voltage Vconf making it possible to position the electrical connection element respectively in a position not forming a contact between the electrical connection element and the associated contact pad and in a position making it possible to form a good electrical contact between the electrical connection element and the associated contact pad. The block diagram of such a method according to a third embodiment is shown in FIG. 9.

As described previously, step 104 making it possible to select a reference electrical connection element A is implemented (with potentially the implementation of step 102 of selection of the set T of electrical connection elements depending on the electronic device used for the method). One of the electrical connection elements is selected as the test connection element B (step 106).

The method is then implemented by carrying out, at step 108, not the measurement of I(P) or R(P), but by carrying out the measurement of I(Vconf) or R(conf). Thus, the card 200 is arranged opposite the electronic device and the value of the current flowing between the test connection element B and the reference connection element A (or the electrical resistance between these elements) is measured by varying the polarization voltage Vconf. The value of Vconf varies progressively (incrementation of the value of Vconf at step 112) such that the connection element passes from a state of absence of contact with the contact pad situated opposite it to a state of contact between the connection element and the contact pad. This variation in the polarization voltage Vconf continues until a noise appears on the curve I(Vconf) or R(Vconf) and until the value of the current or the resistance drops or increases abruptly, reflecting the start of the appearance of an open circuit or a short circuit at the contact pad (decision taken at step 110).

Examples of measurements obtained are shown in FIGS. 7 and 8. For each connection element tested, a value Vmin is defined as being a value of the voltage

Vconf for which the connection element is not yet in contact with the contact pad that is associated with it (zero current I or resistance R of infinite value). A value Vmax is also defined as being a value of the voltage Vconf situated between Vmin and that for which noise appears, for example around the middle of the plateau formed on the curve I(Vconf) or R(Vconf) (substantially at equal distance between the value of Vconf for which I=Icontact and the value of Vconf from which noise appears). Thus, the value Vmin makes it possible to position the connection element such that there is no contact with the contact pad and the value Vmax makes it possible to position the connection element such that a good electrical contact is obtained with the contact pad. The values Vmin and Vmax are determined at step 114.

The process is reiterated for all of the electrical connection elements, the position of which is configurable, which are intended to be tested (steps 116, 118, 120, 122).

In this configuration, the measurement of the current or the resistance may be stopped for example from the appearance of noise on the curves I(Vconf) or R(Vconf).

A calculation by interpolation to determine the values Vmin and Vmax for the electrical connection elements not tested is potentially implemented if all of the electrical connection elements have not been tested (step 140).

The values Vmin and Vmax determined may be memorized in a register which is supplied with the electrical connection device for its reconfiguration during the use of the device.

As in the two first embodiments described previously, it is possible to apply weighting coefficients to the values Vmin and Vmax, with in this case the method implemented while considering X % of Vmin and Y % of Vmax.

In a variant, steps analogous to steps 124, 126, 128, 130, 132, 134, 136 and 138 of the methods described previously in conjunction with FIGS. 2 and 5 may be implemented after step 120 of the method described above in conjunction with FIG. 9. Such steps are implemented while considering the values Vmin, Vmax and Vdest instead of the values Pmin, Pmax and Pdest.

In the embodiments and examples described previously, the characterization method is implemented to characterize a probe card intended to be used to test a functional electronic device. It is also possible that these methods are implemented to characterize electrical connection devices used to produce so-called “3D” electronic circuits, that is to say electronic circuits comprising devices stacked one upon the other, the electrical connection elements corresponding in this case to “micro-inserts”, or more generally any type of electrical connection device comprising electrical connection elements and intended to be hybridized to an electronic device comprising contact pads.

1. A method for characterizing an electrical connection device intended to be hybridized to an electronic device and comprising electrical connection elements each intended to be in electrical contact with at least one of a plurality of contact pads of the electronic device which are electrically connected together, including at least one step of selection of a reference electrical connection element from among said electrical connection elements, then, for the or each of the electrical connection elements other than the reference electrical connection element, the implementation of the following steps:
application of a reference electric voltage between the reference electrical connection element and said electrical connection element;
measurement of an electric current flowing through the reference electrical connection element and said electrical connection element, or of an electrical resistance between the reference electrical connection element and said electrical connection element, by varying the position of said electrical connection element with respect to one of the contact pads arranged opposite said electrical connection element;
determination of the existence of at least one value of a parameter linked to the position of said electrical connection element for which an electrical contact is correctly established between said electrical connection element and said contact pad.

2. The method according to claim 1, in which the electrical connection device comprises a probe card and the electrical connection elements comprise electrical connection probes.

3. The method according to claim 1, in which the step of measurement of the current or of the electrical resistance is carried out from a first position of said electrical connection element in which said electrical connection element is not in contact with said contact pad and at least up to a second position of said electrical connection element from which the current or the electrical resistance measured no longer varies uniformly.

4. The method according to claim 3, in which the step of measurement of the current or of the electrical resistance is carried out up to a third position of said electrical connection element forming an open circuit or a short circuit at said contact pad.

5. The method according to claim 1, in which the plurality of contact pads of the electronic device correspond to the set of contact pads of the electronic device.

6. The method according to claim 1, in which said plurality of contact pads of the electronic device correspond to a part of the set of contact pads of the electronic device, and when the set of contact pads of the electronic device comprises other contact pads of the electronic device which are electrically connected together and distinct from said plurality of contact pads, the steps of the method are repeated for other electrical connection elements of the electrical connection device which are intended to be in contact with said other contact pads.

7. The method according to claim 1, in which the variation of the position of said electrical connection element with respect to said contact pad is carried out by varying a pressure with which the electrical connection device is applied against the electronic device, said pressure corresponding to the parameter linked to the position of said electrical connection element.

8. The method according to claim 1, in which each electrical connection element of the electrical connection device comprises a controllable element able to modify the position thereof with respect to a contact pad of the electronic device arranged opposite the electrical connection element independently of the position of the other electrical connection elements and as a function of the value of a configuration electric voltage applied to the controllable element, and in which the variation of the position of said electrical connection element with respect to said contact pad is carried out by varying the configuration electric voltage applied to the controllable element, of said electrical connection element, said configuration electric voltage corresponding to the parameter linked to the position of said electrical connection element.

9. The method according to claim 8, in which each electrical connection element comprises at least:
one support of which at least one first end is anchored to a substrate of the electrical connection device such that a part of the support is suspended above a front face of the electrical connection device, the support comprising at least one portion of piezoelectric material arranged between two electrodes and able to move said part of the support in a two-directional manner substantially perpendicularly to the front face as a function of the value of the configuration electric voltage applied to the electrodes;
one electrically conducting element arranged on said part of the support.

10. The method according to claim 7, in which the determination of the existence of at least one value of a parameter linked to the position of said electrical connection element and for which an electrical contact is correctly established between said electrical connection element and said contact pad comprises at least the implementation of the following steps:
determination of a value Fmin of the parameter linked to the position of said electrical connection element for which the electrical contact between said electrical connection element and said contact pad is correctly established and from which the current or the electrical resistance measured varies uniformly;
determination of a value Fmax of the parameter linked to the position of said electrical connection element for which the electrical contact between said electrical connection element and said contact pad is correctly established and from which the current or the electrical resistance measured no longer varies uniformly;
determination of an interval of values [X % of Fmin; Y % of Fmax], X and Y being coefficients of values between around 75 and 125.

11. The method according to claim 10, further comprising a step of determination of the existence of an intersection of the intervals of values [X % of Fmin; Y % of Fmax] for all or part of the electrical connection elements other than the reference electrical connection element.

12. The method according to claim 11, in which the determination of at least one value of a parameter linked to the position of said electrical connection element and for which an electrical contact is correctly established between said electrical connection element and said contact pad further comprises a step of determination of a value Fdest of the parameter linked to the position of said electrical connection element from which a variation of the current or of the electrical resistance measured increases due to a deterioration of said contact pad, and further comprising, when it is determined that an intersection of the intervals of values [X % of Fmin; Y % of Fmax] does not exist, a step of determination of the existence of an intersection of the intervals of values [X % of Fmin; Z % of Fdest] determined previously, with Z between around 75 and 95.

13. The method according to claim 6, in which the determination of at least one value of a parameter linked to the position of said electrical connection element and for which an electrical contact is correctly established between said electrical connection element and said contact pad further comprises a step of determination of a value Fdest of the parameter linked to the position of said electrical connection element from which a variation of the current or of the electrical resistance measured increases due to a deterioration of said contact pad, and further comprising, when it is determined that an intersection of the intervals of values [X % of Fmin; Y % of Fmax] does not exist, a step of determination of the existence of an intersection of the intervals of values [X % of Fmin; Z % of Fdest] determined previously, with Z between around 75 and 95,
and further comprising, when it is determined that an intersection of the intervals of values [X % of Fmin; Y % of Fmax] exists, a step of calculation by interpolation of an interval of values [X % of Fmin; Y % of Fmax] for each of the electrical connection elements of the electrical connection device for which an interval of values [X % of Fmin; Y % of Fmax] has not been determined previously and, when it is determined that an intersection of the intervals of values [X % of Fmin; Z % of Fdest] exists, a step of calculation by interpolation of intervals of values [X % of Fmin; Z % of Fdest] for each of the electrical connection elements of the electrical connection device for which an interval of values [X % of Fmin; Z % of Fdest] has not been determined previously.

14. The method according to claim 8, in which the determination of at least one value of a parameter linked to the position of said electrical connection element and for which an electrical contact is correctly established between said electrical connection element and said contact pad comprises at least the implementation of the following steps:
determination of a value Vmin of the configuration electric voltage for which said electrical connection element is not in contact with said contact pad;
determination of a value Vmax of the configuration electric voltage for which an electrical contact is correctly established between said electrical connection element and said contact pad without deteriorating said contact pad.

15. The method according to claim 14, in which the value Vmax of the configuration electric voltage positions said electrical connection element in an intermediate position between a first position for which an electrical contact is correctly established between said electrical connection element and said contact pad and from which the current or the electrical resistance measured varies uniformly and a second position for which an electrical contact is correctly established between said electrical connection element and said contact pad and from which the current or the electrical resistance measured no longer varies uniformly.
